(19) United States
(12) Patent Application Publication
(10) Pub. No.: US 2004/0079285 A1
(43) Pub. Date: Apr. 29, 2004

(54) Automation of oxide material growth in molecular beam epitaxy systems

(75) Inventors: Hao Li, Chandler, AZ (US); Ravindranath Droopad, Chandler, AZ (US); Dirk Jordan, Gilbert, AZ (US); Corey Overgaard, Phoenix, AZ (US); Zhiyi Yu, Gilbert, AZ (US)

Correspondence Address: OBLON, SPIVAK, MCCLELLAND, MAIER & NEUSTADT, P.C., 1940 DUKE STREET, ALEXANDRIA, VA, 22314, US

(73) Assignee: MOTOROLA, INC., Schaumburg, IL

(21) Appl. No.: 10/279,078

(22) Filed: Oct. 24, 2002

(51) Int. Cl. C23C 16/00; H01L 21/306

(52) U.S. Cl. 118/715; 156/345.33

(57) ABSTRACT

High quality epitaxial layers of monocrystalline materials (26) can be grown overlying monocrystalline substrates (22) such as large silicon wafers by forming a compliant substrate for growing the monocrystalline layers. An accommodating buffer layer (24) comprises a layer of monocrystalline oxide spaced apart from a silicon wafer by an amorphous interface layer (28) of silicon oxide. The amorphous interface layer dissipates strain and permits the growth of a high quality monocrystalline oxide accommodating buffer layer. The growth of the monocrystalline oxide film for accommodating buffer layer (24) is achieved through an automated oxygen delivery system (200) that controls a variety of oxygen control parameters, such as pressure control, ramp control, and flow control. The oxygen delivery system (200) is preferably a dual stage pressure control system (204, 206) with the ability to precisely control the oxygen profile in the growth chamber. The oxygen delivery system (200) allows total automation of oxide film growth in an MBE chamber (102).

### FIELD OF THE INVENTION

This invention relates generally to semiconductor wafer fabrication, and more specifically to the equipment and processes for manufacturing such wafers.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and electron lifetime of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

The use of molecular beam epitaxy (MBE) is a preferred process for the growth of oxide films. In current MBE systems, process automation is realized by controlling shutters, however, shutters cannot control gaseous species such as oxygen, which is essential for oxide growth. Traditionally, oxygen is introduced into a chamber by opening leak valves. The oxygen partial pressure is then controlled by manually varying the leak valve position. However, this manual control prohibits the automation of oxide growth processes and inherently introduces human factors in the growth of the oxide films. Human error and variations between operators can result in inconsistent material profiles within a batch of wafers. Thus, process automation is extremely desirable for the realization of batch production semiconductor wafers.

If a semiconductor wafer fabrication system were available that eliminated the need for manual oxygen control, the integrity of the thin films could be maintained and manufacturing costs could be reduced.

Accordingly, a need exists for a semiconductor manufacturing apparatus and technique that provides improved control over the growth of oxide materials, particularly in MBE systems.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIG. 13 is a block diagram of an oxygen delivery system in accordance with the present invention;

FIG. 14 schematically illustrates the oxygen delivery system in accordance with a preferred embodiment of the invention;

FIG. 15 is a flowchart depicting an exemplary process of forming an oxide material over a monocrystalline substrate for subsequent III-V growth in accordance with the preferred embodiment;

FIG. 16 is an example of an oxygen profile achieved with the two-stage oxygen delivery system of the preferred embodiment;

FIG. 17 schematically illustrates an expansion of the system of FIG. 14 in accordance with an alternative embodiment of the invention;

FIG. 18 schematically illustrates an expansion of the system of FIG. 17 in accordance with another alternative embodiment of the invention;

FIG. 19 is a flowchart depicting an exemplary process of forming an oxide material over a monocrystalline substrate for subsequent III-V growth using a two stage deposition approach in accordance with an alternative embodiment of the invention; and

FIG. 20 is an example of an oxygen profile achieved with the two-stage system using the two-stage deposition approach described for the process of FIG. 19 in accordance with the alternative embodiment of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

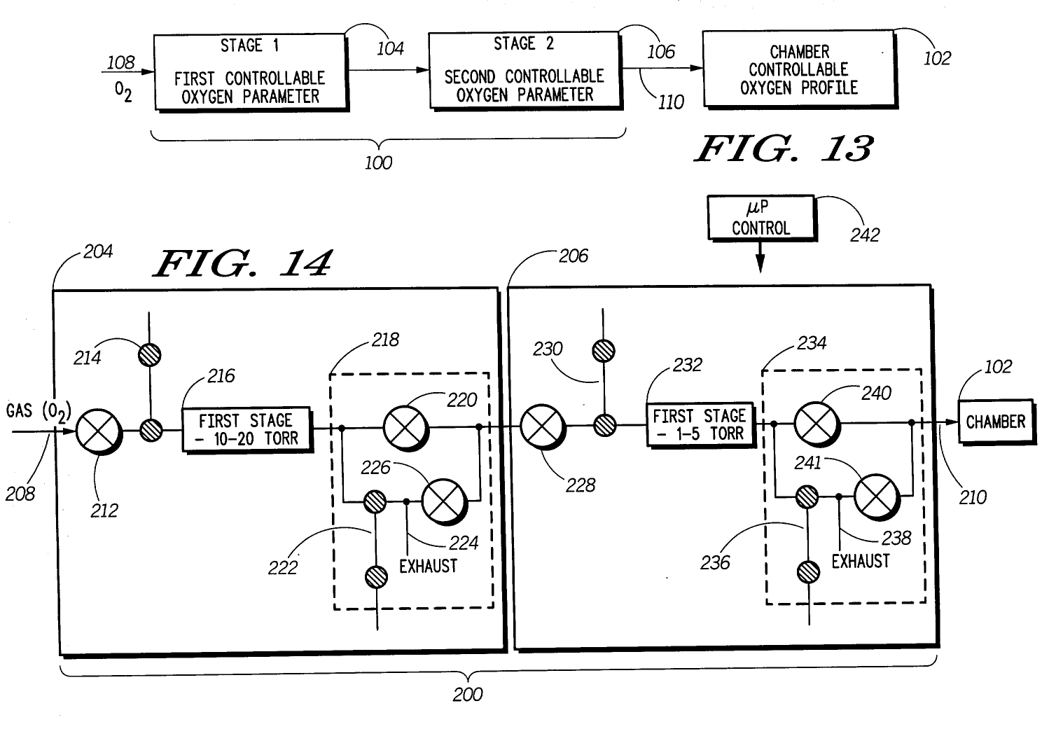

The following application initially provides for the formation of high quality epitaxial layers of monocrystalline materials grown overlying monocrystalline substrates. The formation of these structures is described with reference to FIGS. 1-12. As will be described herein, the formation of such structures also involves the growth of oxide films. An apparatus and process providing for automated growth of the oxide films is provided herein by the description pertaining to FIGS. 13-20.

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Substrate 22 may also be, for example, silicon-on-insulator (SOI), where a thin layer of silicon is on top of an insulating material such as silicon oxide or glass. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and other perovskite oxide materials, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxides or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), mixed II-VI compounds, Group IV and VI elements (IV-VI semiconductor compounds), mixed IV-VI compounds, Group IV elements (Group IV semiconductors), and mixed Group IV compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe), silicon (Si), germanium (Ge), silicon germanium (SiGe), silicon germanium carbide (SiGeC), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

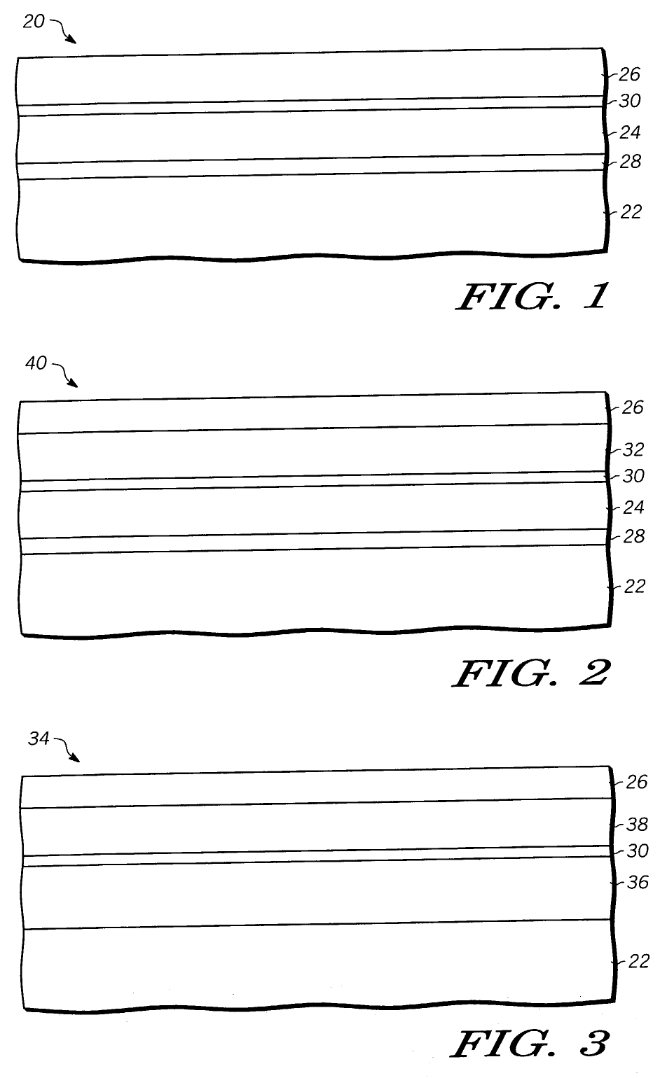

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer 32 is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer may then be optionally exposed to an anneal process to convert at least a portion of the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides strain relief for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming at least a portion of a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV, monocrystalline compound semiconductor materials, or other monocrystalline materials including oxides and nitrides.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate typically (001) oriented. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The lattice structure of the resulting crystalline oxide exhibits a substantially 45-degree rotation with respect to the substrate silicon lattice structure. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by depositing a surfactant layer comprising one element of the compound semiconductor layer to react with the surface of the oxide layer that has been previously capped. The capping layer is preferably up to 3 monolayers of Sr—O, Ti—O, strontium or titanium. The template layer is preferably of Sr—Ga, Ti—Ga, Ti—As, Ti—O—As, Ti—O—Ga, Sr—O—As, Sr—Ga—O, Sr—Al—O, or Sr—Al. The thickness of the template layer is preferably about 0.5 to about 10 monolayers, and preferably about 0.5-3 monolayers. By way of a preferred example 0.5-3 monolayers of Ga deposited on a capped Sr—O terminated surface have been illustrated to successfully grow GaAs layers. The resulting lattice structure of the compound semiconductor material exhibits a substantially 45-degree rotation with respect to the accommodating buffer layer lattice structure.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 4 nm to ensure adequate crystalline and surface quality and is formed of monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a substantially 45-degree rotation with respect to the substrate silicon lattice structure.

An accommodating buffer layer formed of these zirconate or hafnate materials is suitable for the growth of a monocrystalline material layer which comprises compound semiconductor materials in an indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is about 0.5-10 monolayers of one of a material M—N and a material M—O—N, wherein M is selected from at least one of Zr, Hf, Ti, Sr, and Ba; and N is selected from at least one of As, P, Ga, Al, and In. Alternatively, the template may comprise 0.5-10 monolayers of gallium (Ga), aluminum (Al), indium (In), or a combination of gallium, aluminum or indium, zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 0.5-2 monolayers of one of these materials. By way of an example, for a barium zirconate accommodating buffer layer, the surface is terminated with 0.5-2 monolayers of zirconium followed by deposition of 0.5-2 monolayers of arsenic to form a Zr—As template. A monocrystalline layer of the compound semiconductor material from the indium phosphide system is then grown on the template layer. The resulting lattice structure of the compound semiconductor material exhibits a substantially 45 degree rotation with respect to the accommodating buffer layer lattice structure and a lattice mismatch between the buffer layer and (100) oriented InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 3-10 nm. The lattice structure of the resulting crystalline oxide exhibits a substantially 45-degree rotation with respect to the substrate silicon lattice structure. Where the monocrystalline layer comprises a compound semiconductor material, the II-VI compound semiconductor material can be, for example, zinc selenide (ZnSe) or zinc sulfur selenide (ZnSSe). A suitable template for this material system includes 0.5-10 monolayers of zinc-oxygen (Zn—O) followed by 0.5-2 monolayers of an excess of zinc followed by the selenidation of zinc on the surface. Alternatively, a template can be, for example, 0.5-10 monolayers of strontium-sulfur (Sr—S) followed by the ZnSSe.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a substantial (i.e., effective) match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The superlattice period can have a thickness of about 2-15 nm, preferably 2-10 nm. The template for this structure can be the same as that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about 0.5-2 monolayers can be used as a nucleating site for the subsequent growth of the monocrystalline material layer which in this example is a compound semiconductor material. The formation of the oxide layer is capped with either a 0.5-2 monolayer of strontium or a 0.5-2 monolayer of titanium to act as a nucleating site for the subsequent deposition of the monocrystalline germanium. The layer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0% at the monocrystalline material layer 26 to about 50% at the accommodating buffer layer 24. The additional buffer layer 32 preferably has a thickness of about 10-30 nm. Varying the composition of the buffer layer from GaAs to InGaAs serves to provide an effective (i.e. substantial) lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z} TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 1 nm to about 100 nm, preferably about 1-10 nm, and more preferably about 3-5 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 nm to about 500 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

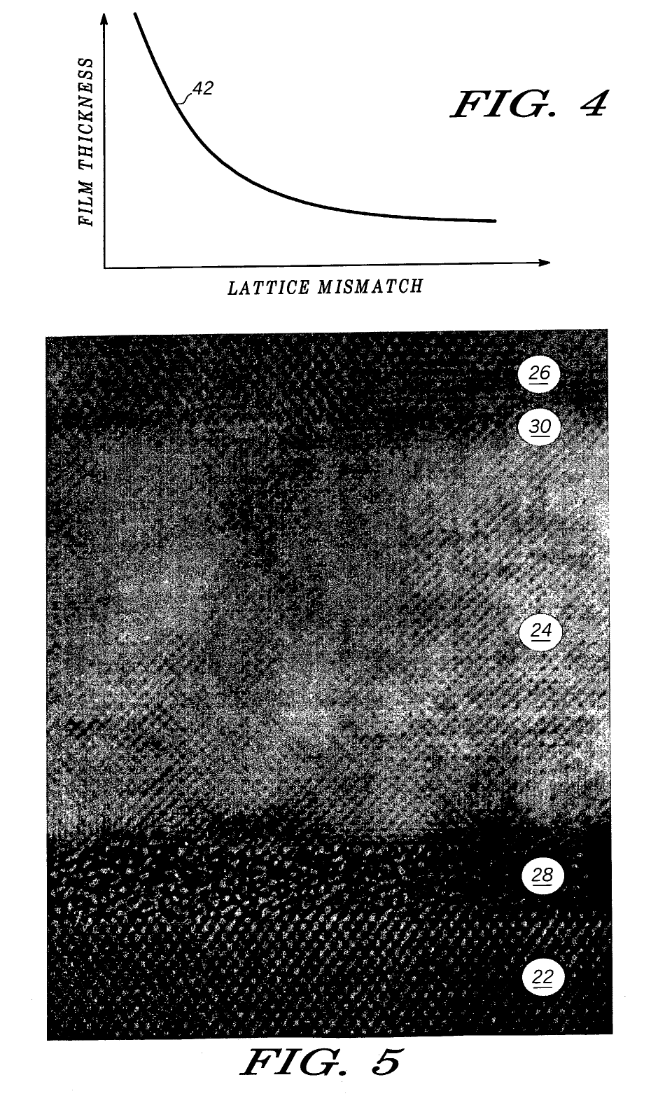

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is typically a (001) oriented monocrystalline silicon wafer and accommodating buffer layer 24 is a layer of strontium barium titanate. Substantial (i.e., effective) matching of lattice constants between these two materials is achieved by rotating the crystal orientation of the titanate material by approximately 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by substantially 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by substantially 45° with respect to the host oxide crystal. In some instances, a crystalline semiconductor buffer layer 32 between the host oxide and the grown monocrystalline material layer 26 can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is oriented on axis or, at most, about 6° off axis, and preferably misoriented 1-3° off axis toward the [110] direction. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer (preferably 1-3 monolayers) of strontium, barium, a combination of strontium and barium, or other alkaline earth metals or combinations of alkaline earth metals in an MBE apparatus. In the case where strontium is used, the substrate is then heated to a temperature above 720° C. as measured by an optical pyrometer to cause the strontium to react with the native silicon oxide layer. The strontium serves to reduce the silicon oxide to leave a silicon oxide-free surface. The resultant surface may exhibit an ordered (2×1) structure. If an ordered (2×1) structure has not been achieved at this stage of the process, the structure may be exposed to additional strontium until an ordered (2×1) structure is obtained. The ordered (2×1) structure forms a template for the ordered growth of an overlying layer of a monocrystalline oxide. The template provides the necessary chemical and physical properties to nucleate the crystalline growth of an overlying layer.

It is understood that precise measurement of actual temperatures in MBE equipment, as well as other processing equipment, is difficult, and is commonly accomplished by the use of a pyrometer or by means of a thermocouple placed in close proximity to the substrate. Calibrations can be performed to correlate the pyrometer temperature reading to that of the thermocouple. However, neither temperature reading is necessarily a precise indication of actual substrate temperature. Furthermore, variations may exist when measuring temperatures from one MBE system to another MBE system. For the purpose of this description, typical pyrometer temperatures will be used, and it should be understood that variations may exist in practice due to these measurement difficulties.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of above 720° C. At this temperature a solid-state reaction takes place between the strontium oxide and the native silicon oxide causing the reduction of the native silicon oxide and leaving an ordered (2×1) structure on the substrate surface. If an ordered (2×1) structure has not been achieved at this stage of the process, the structure may be exposed to additional strontium until an ordered (2×1) structure is obtained. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-600° C., preferably 350°-550° C., and a layer of strontium titanate is grown on the template layer by molecular beam epitaxy. The MBE process can be initiated by opening shutters in the MBE apparatus to expose strontium, titanium and oxygen sources. (A further embodiment providing for automated delivery of oxygen to the MBE chamber is provided with reference to FIGS. 13-20, to be described later.) The ratio of strontium and titanium is approximately 1:1. The partial pressure of oxygen is initially set at a minimum value to grow stoichiometric strontium titanate at a growth rate of about 0.1-0.8 nm per minute, preferably 0.3-0.5 nm per minute. After initiating growth of the strontium titanate, the partial pressure of oxygen is increased above the initial minimum value. The stoichiometry of the titanium can be controlled during growth by monitoring RHEED patterns and adjusting the titanium flux. The overpressure of oxygen causes the growth of an amorphous silicon oxide layer at the interface between the underlying substrate and the strontium titanate layer. This step may be applied either during or after the growth of the strontium titanate layer. The growth of the amorphous silicon oxide layer results from the diffusion of oxygen through the strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with up to 2 monolayers of titanium, up to 2 monolayers of strontium, up to 2 monolayers of titanium-oxygen or with up to 2 monolayers of strontium-oxygen. Following the formation of this capping layer, arsenic is deposited to form a Ti—As bond, a Ti—O—As bond or a Sr—O—As bond. Any of these form an appropriate template for deposition and formation of a gallium arsenide monocrystalline layer. Following the formation of the template, gallium is subsequently introduced to the reaction with the arsenic and gallium arsenide forms. Alternatively, 0.5-3 monolayers of gallium can be deposited on the capping layer to form a Sr—O—Ga bond, or a Ti—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed, which relieves strain due to lattice mismatch. GaAs compound semiconductor layer 26 was then grown epitaxially using template layer 30.

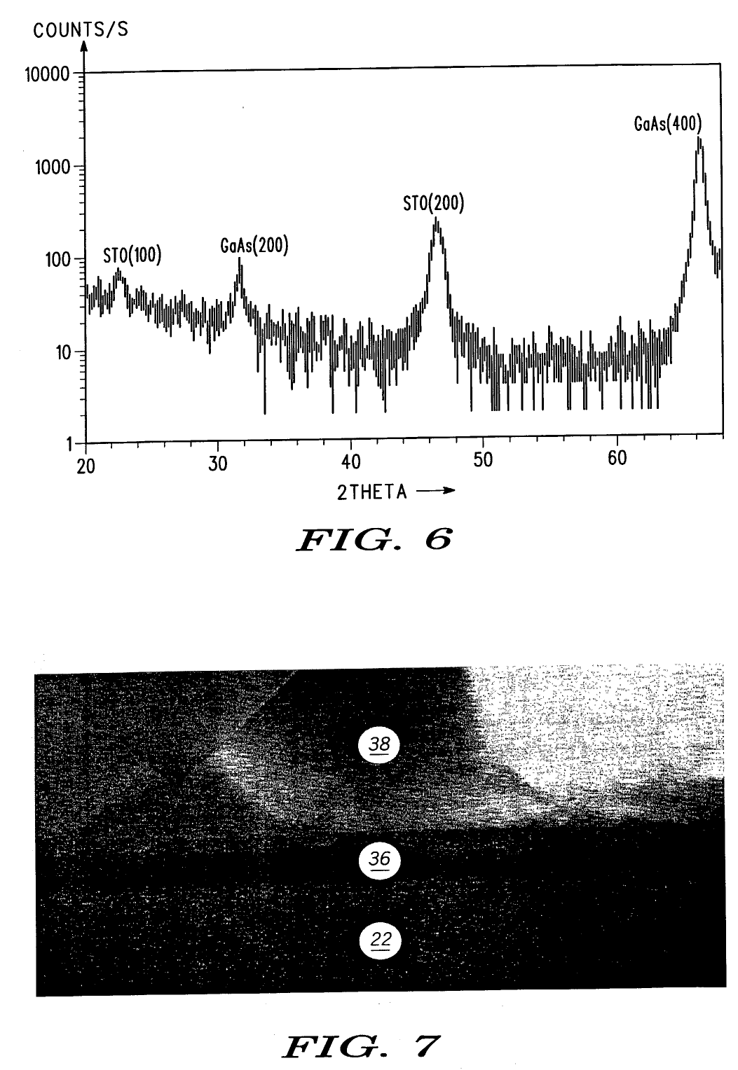

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) oriented.

The structure illustrated in FIG. 2 can be formed by the process discussed above with the addition of an additional buffer layer deposition step. The additional buffer layer 32 is formed overlying the template layer 30 before the deposition of the monocrystalline material layer 26. If the additional buffer layer 32 is a monocrystalline material comprising a compound semiconductor superlattice, such a superlattice can be deposited, by MBE for example, on the template 30 described above. If instead, the additional buffer layer is a monocrystalline material layer comprising a layer of germanium, the process above is modified to cap the first buffer layer of strontium titanate with a final template layer of either strontium or titanium and then by depositing germanium to react with the strontium or titanium. The germanium buffer layer can then be deposited directly on this template.

Structure 34, illustrated in FIG. 3, may be formed by growing an accommodating buffer layer 24, forming an amorphous oxide layer 28 over substrate 22, and growing semiconductor layer 38 over the accommodating buffer layer, as described above. The accommodating buffer layer 24 and the amorphous oxide layer 28 are then exposed to a higher temperature anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer 24, the amorphous oxide layer 28, and monocrystalline layer 38 to a rapid thermal anneal process with a peak temperature of about 700° C. to about 1000° C. (actual temperature) and a process time of about 5 seconds to about 20 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 38 may be required to prevent degradation of layer 38 during the anneal process. For example, when layer 38 includes GaAs, the anneal environment preferably includes an overpressure of arsenic to mitigate degradation of layer 38. Alternately, an appropriate anneal cap, such as silicon nitride, may be utilized to prevent the degradation of layer 38 during the anneal process with the anneal cap being removed after the annealing process.

As noted above, layer 38 of structure 34 may include any materials suitable for either of layers 32 or 26. Accordingly, any deposition or growth methods described in connection with either layer 32 or 26 may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

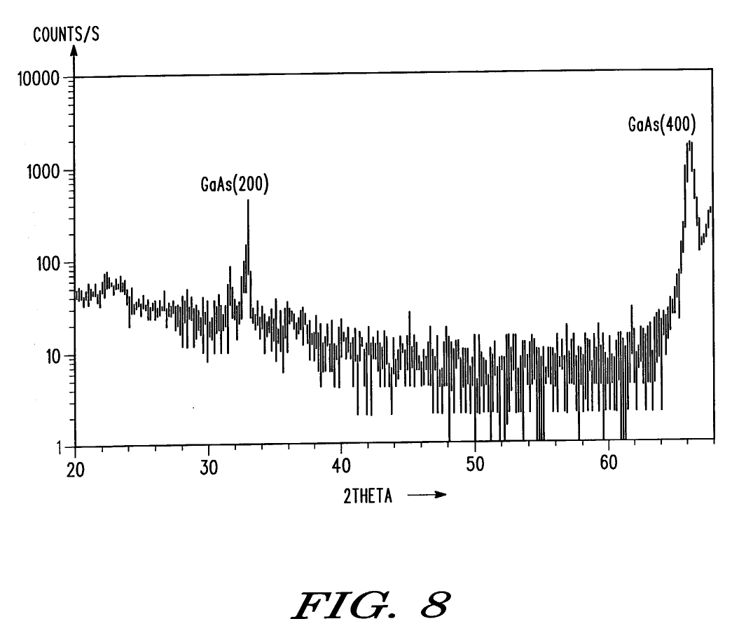

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) oriented and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. (An automated oxygen delivery system for use in the MBE process will be described later with reference to FIGS. 13-20.) The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, niobates, alkaline earth metal tin-based perovskites, lanthanum aluminate, lanthanum scandium oxide, and gadolinium oxide can also be grown. Further, by a similar process such as MBE, other monocrystalline material layers comprising other III-V, II-VI, and IV-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide, respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen, and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

Single crystal silicon has 4-fold symmetry. That is, its structure is essentially the same as it is rotated in 90-degree steps in the plane of the (001) surface. Likewise, strontium titanate and many other oxides have a 4-fold symmetry. On the other hand, GaAs and related compound semiconductors have a 2-fold symmetry. The 0 degree and 180 degree rotations of the 2-fold symmetry are not the same as the 90 degree and 270 degree rotations of the 4-fold symmetry. If GaAs is nucleated upon strontium titanate at multiple locations on the surface, two different phases are produced. As the material continues to grow, the two phases meet and form anti-phase domains. These anti-phase domains can have an adverse effect upon certain types of devices, particularly minority carrier devices like lasers and light emitting diodes.

In accordance with one embodiment of the present invention, in order to provide for the formation of high quality monocrystalline compound semiconductor material, the starting substrate is off-cut or misoriented from the ideal (100) orientation by 0.5 to 6 degrees in any direction, and preferably 1 to 2 degrees toward the [110] direction. This offcut provides for steps or terraces on the silicon surface and it is believed that these substantially reduce the number of anti-phase domains in the compound semiconductor material, in comparison to a substrate having an offcut near 0 degrees or off cuts larger than 6 degrees. The greater the amount of off-cut, the closer the steps and the smaller the terrace widths become. At very small angles, nucleation occurs at other than the step edges, decreasing the size of single-phase domains. At high angles, smaller terraces decrease the size of single-phase domains. Growing a high quality oxide, such as strontium titanate, upon a silicon surface causes surface features to be replicated on the surface of the oxide. The step and terrace surface features are replicated on the surface of the oxide, thus preserving directional cues for subsequent growth of compound semiconductor material. Because the formation of the amorphous interface layer occurs after the nucleation of the oxide has begun, the formation of the amorphous interface layer does not disturb the step structure of the oxide.

After the growth of an appropriate accommodating buffer layer, such as strontium titanate or other materials as described earlier, a template layer is used to promote the proper nucleation of compound semiconductor material. In accordance with one embodiment, the strontium titanate is capped with up to 2 monolayers of SrO. The template layer 30 for the nucleation of GaAs is formed by raising the substrate to a temperature in the range of 540 to 630 degrees and exposing the surface to gallium. The amount of gallium exposure is preferably in the range of 0.5 to 5 monolayers. It is understood that the exposure to gallium does not imply that all of the material will actually adhere to the surface. Not wishing to be bound by theory, it is believed that the gallium atoms adhere more readily at the exposed step edges of the oxide surface. Thus, subsequent growth of gallium arsenide preferentially forms along the step edges and prefer an initial alignment in a direction parallel to the step edge, thus forming predominantly single domain material. Other materials besides gallium may also be utilized in a similar fashion, such as aluminum and indium or a combination thereof.

After the deposition of the template, a compound semiconductor material such as gallium arsenide may be deposited. The arsenic source shutter is preferably opened prior to opening the shutter of the gallium source. Small amounts of other elements may also be deposited simultaneously to aid nucleation of the compound semiconductor material layer. For example, aluminum may be deposited to form AlGaAs. As noted above, layer 38, illustrated in FIG. 3, comprises a monocrystalline material that can be grown epitaxially over a monocrystalline oxide material, such as material used to form accommodating buffer layer 24. In accordance with one embodiment of the invention, layer 38 includes materials different from those used to form layer 26. For example, in a preferred embodiment, layer 38 includes AlGaAs, which is deposited as a nucleation layer at a relatively slow growth rate. For example, the growth rate of layer 38 of AlGaAs can be approximately 0.10-0.5 μm/hr. In this case, growth can be initiated by first depositing As on template layer 30, followed by deposition of aluminum and gallium. Deposition of the nucleation layer generally is accomplished at about 300-600° C., and preferably 400-500° C. In accordance with one exemplary embodiment of the invention, the nucleation layer is about 1 nm to about 500 nm thick, and preferably 5 nm to about 50 nm. In this case, the aluminum source shutter is preferably opened prior to opening the gallium source shutter. The amount of aluminum is preferably in the range from 0 to 50% (expressed as a percentage of the aluminum content), and is most preferably about 15-25%. Other materials, such as InGaAs, could also be used in a similar fashion. Once the growth of compound semiconductor material is initiated, other mixtures of compound semiconductor materials can be grown with various compositions and various thicknesses as required for various applications. For example, a thicker layer of GaAs may be grown on top of the AlGaAs layer to provide a semi-insulating buffer layer prior to the formation of device layers.

The quality of the compound semiconductor material can be improved by including one or more in-situ anneals at various points during the growth. The growth is interrupted, and the substrate is raised to a temperature of between 500°-650° C., and preferably about 550°-600° C. The anneal time depends on the temperature selected, but for an anneal of about 550° C., the length of time is preferably about 15 minutes. The anneal can be performed at any point during the deposition of the compound semiconductor material, but preferably is performed when there is 50 nm to 500 nm of compound semiconductor material deposited. Additional anneals may also be done, depending on the total thickness of material being deposited.

In accordance with one embodiment, monocrystalline material layer 26 is GaAs. Layer 26 may be deposited on layer 24 at various rates, which may vary from application to application; however in a preferred embodiment, the growth rate of layer 26 is about 0.2 to 1.0 μm/hr. The temperature at which layer 26 is grown may also vary, but in one embodiment, layer 26 is grown at a temperature of about 300°-600° C. and preferably about 350°-500° C.

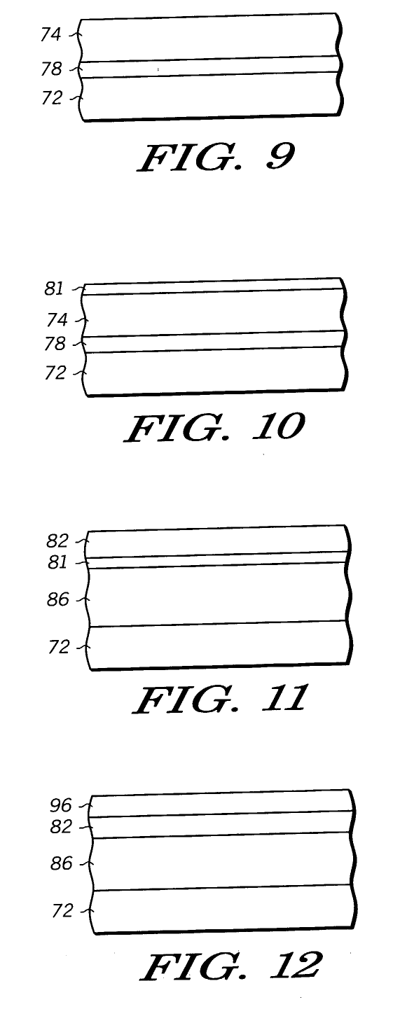

Turning now to FIGS. 9-12, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 9. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, or the like as illustrated in FIG. 10 with a thickness of a few tens of nanometers but preferably with a thickness of about 5 nm. Monocrystalline oxide layer 74 preferably has a thickness of about 2 to 10 nm.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 11. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, as shown in FIG. 12, a compound semiconductor layer 96, such as gallium nitride (GaN), is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature and high power RF applications and optoelectronics. GaN systems have particular use in the photonic industry for the blue/green and UV light sources and detection. High brightness light emitting diodes (LEDs) and lasers may also be formed within the GaN system.

FIGS. 1-12 provided for the formation of high quality epitaxial layers of monocrystalline materials grown overlying monocrystalline substrates. As described previously, the formation of these structures involved the growth of oxide films, such as accommodating buffer layer 24 and amorphous intermediate layer 28 of FIG. 1 and accommodating buffer layer 74 and amorphous interface layer 78 of FIG. 9, preferably using MBE processing. The MBE process can be initiated by opening leak valves (a manual operation) in the MBE apparatus to expose gaseous sources to form the oxide film over the substrate as explained earlier. In accordance with the present invention, an apparatus and process providing for automated growth of oxide films in an MBE system is provided by the description of FIGS. 13-20 to follow.

FIG. 13 schematically illustrates an oxygen delivery system 100 in accordance with the present invention. Oxygen delivery system 100 is configured to automatically control the delivery of oxygen to a chamber 102 for the fabrication of semiconductor structures having multiple monocrystalline material layers described in FIGS. 1-12. In accordance with the present invention, oxygen delivery system 100 provides an entirely automated means for forming an oxide material over a monocrystalline substrate for subsequent III-V growth (or other growth as described in FIGS. 1-12).

Oxygen delivery system 100 is preferably formed of first and second stages 104, 106 respectively. In accordance with the present invention, the first stage 104 provides a first controllable oxygen parameter and the second stage provides a second controllable oxygen parameter. The first stage 104 includes an input 108 for receiving oxygen gas. The first stage 104 controls and adjusts the delivery of the oxygen gas to the second stage using the first controllable oxygen parameter. The second stage 106 receives the gas from the first stage and makes further adjustments to the oxygen gas through the second controllable oxygen parameter. The second stage 106 includes an output 110 for the delivery of the oxygen gas to the chamber 102. In accordance with the present invention, the first and second controllable oxygen parameters provide a controllable oxygen profile within the chamber 102. The oxygen output can be delivered to the chamber 102 using one of a variety of known mechanisms, such as a shower head, an orifice, or a plasma generator, to name a few. Chamber 102 is preferably a single chamber having a plurality of gaseous or elemental material sources, however the oxygen delivery system 100 can be used in conjunction with multi-chamber environments as well. While chamber 102 is preferably an MBE reactor, chamber 102 may comprise other types of deposition reactors such as PLD, Sputtering, evaporation, or many other PVD systems.

The oxygen delivery system 100 of the present invention can be used in a single stage format for some applications, but a dual stage (as shown) or multi-stage format is preferred. Each stage controls a parameter of the oxygen gas. The oxygen control parameters include, but are not limited to, partial pressure, ramp level, flow rate, etc. System 100 can be implemented in a variety of ways, but preferably includes a plurality of pneumatically controlled valves, plunger valves, throttle valves, pressure gauges, and exhausts/pumps-all operatively coupled to form an automated pressure control system responsive to oxygen parameter levels.

Referring now to FIG. 14, there is shown an oxygen delivery system 200 in accordance with a preferred embodiment of the invention. In accordance with the preferred embodiment, the implementation and operation of oxygen delivery system 200 utilizes pressure control as the parameter of choice for both stages 204, 206. Thus, first stage 204 provides a first oxygen controllable pressure level, and second stage 206 provides a second oxygen controllable pressure level. Chamber 102 is preferably a molecular beam epitaxy (MBE) reactor having the oxygen delivery system 200 coupled thereto.

Briefly, each pressure control stage includes such components as: plunger valves, valves, pressure gauge, exhaust, and pump. A microprocessor control 242 is programmed to adjust the components in response to pressure gauge readings or other control parameters.

In accordance with the preferred embodiment of the invention, gaseous oxygen 208 is injected into oxygen delivery system 200, and the first stage 204 regulates the partial pressure of oxygen to be approximately an order of magnitude higher than the pressure of the second stage 206. For example, if the partial pressure of the first stage 204 is set to about 20 Torr, the second stage partial pressure might be varied from 0.01-5 Torr. This variation is automatically controlled through the microprocessor control 242.

The following description provides a more detailed account of the preferred embodiment of the invention shown in FIG. 14. The first pressure control stage 204 generally includes a first pneumatically controlled valve 212, a first plunger valve 214, a first pressure gauge 216, and a first pump 218, all operatively coupled in series. In operation, the first pneumatically controlled valve 212 controls gas delivery into the system 200 while the plunger 214 acts as an inlet valve. The pressure gauge 216 measures the partial pressure of oxygen within the first stage 204 and operates similarly to a gas reservoir. The first plunger 214 regulates the flow of oxygen into the second stage 206 based on the pressure gauge 216 reading. The first stage 204 further includes an outlet for diverting oxygen gas out of the system using a second valve 220, a second plunger 222, an exhaust 224, and a third pneumatically controlled valve 226.

The second pressure control stage 206 similarly includes a fourth pneumatically controlled valve 228 coupled to the first pressure control stage 204, a third plunger valve 230 coupled to the fourth pneumatically controlled valve, a second pressure gauge 232 coupled to the third plunger valve, and a second pump 234 coupled to the second pressure gauge 232. The second pump 234 includes a fourth plunger valve 236, a second exhaust 238, and a fifth and sixth pneumatically controlled valve 240 and 241.

In the preferred embodiment, oxygen gas enters the second stage 206 by opening the fourth pneumatically controlled valve 228 and pumping plunger 230. The fifth pneumatic control valve 240 can be opened to direct gas delivery either into the chamber 102 or closed to divert the gas into the exhaust 238. The opening or closing of the plunger valves 230 and 236 is based on a reading of the second pressure gauge 232. When the second pressure gauge 232 has a reading below a predetermined level, plunger valve 230 opens to let the oxygen gas into to the system. The fourth plunger valve 236, second exhaust 238, and six pneumatically controlled valve 241 operate to release oxygen gas out of the system based on the second pressure gauge 232 having a reading above the predetermined level.

The equipment used to implement the controllable pressure levels for stages 204, 206 is available from CBE or CVD equipment vendors. The implementation and use of this equipment in an MBE system provides automation of oxide film growth previously unavailable to MBE systems. First and second stages 204, 206 can be built using other types of pressure control equipment as well. Any device that controls pressure can be placed in the first stage 204. For example, a baratron controlled throttle valve can be used in the first stage. This device provides a coarse control over pressure.

Referring back to FIG. 13, the first and second stages can take on a variety of oxygen control parameters through the use of various equipment configurations. As mentioned above, a baratron can be used in the first stage 104 to provide coarse control over pressure. The baratron could be used, for example, along with the second stage 106 implemented as a leak valve to limit the flow of the gas into the chamber 102, thus creating a pressure difference between the first stage and the chamber. Alternatively, a Mass Flow Controller (MFC) can be substituted for the pressure control device in the first stage 104 to regulate oxygen flow as opposed to oxygen pressure. The MFC provides a coarse control over oxygen flow in the first stage 104 and a pressure control device can be used to control the partial pressure of oxygen in the second stage 106. Thus, the oxygen delivery system 100 of the present invention can be altered to vary other combinations of control parameters as well. Thus, the first stage 104 can comprise an oxygen pressure control device and the second stage 106 can comprise an oxygen flow control device. Furthermore, the first stage 104 can comprise an oxygen flow control device, while the second stage 106 comprises an oxygen pressure control device. As another alternative, but with somewhat less control, the first stage 104 can comprise a first oxygen flow control device, and the second stage 106 can comprise a second oxygen flow control device.

Accordingly, various types of oxygen pressure profiles can now be achieved using the oxygen delivery system 100 of the present invention. For example, different equilibrium oxygen partial pressure in the chamber 102 can be obtained by setting different steady state oxygen partial pressure at the first and/or second stage. Different ramping rate of oxygen can be obtained in the chamber by varying the ramp rate of the oxygen partial pressure at the first and/or second stage.

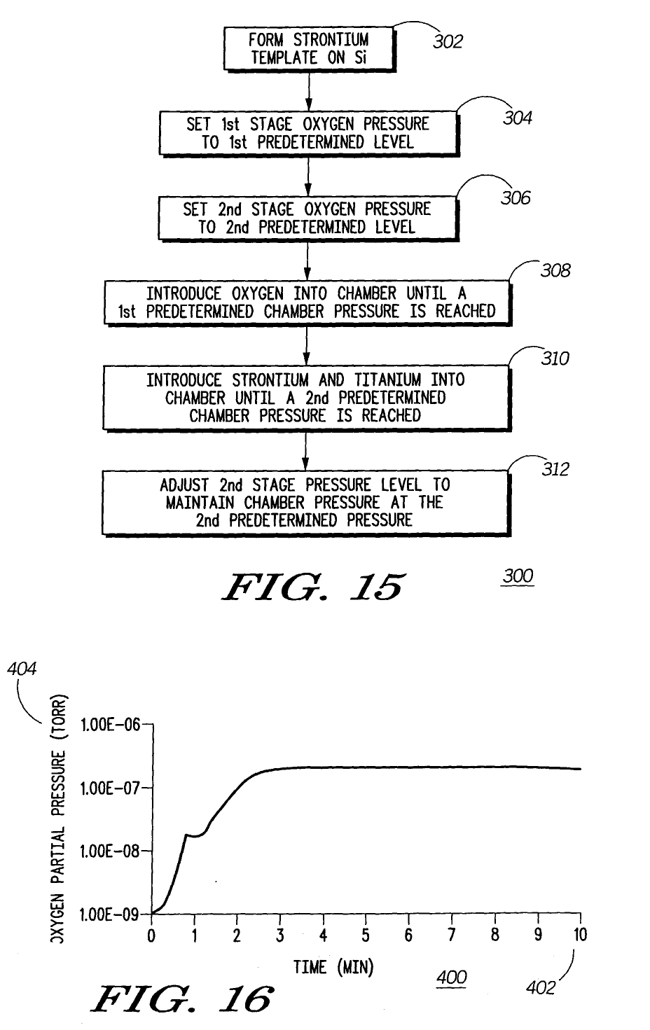

Referring now to FIG. 15, there is shown a flowchart depicting a process 300 of forming an oxide material over a monocrystalline substrate for subsequent III-V growth, (or other subsequent growth as described in reference to FIGS. 1-12). The process 300 described herein is described in terms of forming an STO buffer layer on a monocrystalline silicon substrate but applies to other oxides and monocrystalline substrate materials as well. Process 300 begins by forming a strontium template at step 302, for example a 2× template, on a silicon substrate. The first stage oxygen pressure level is then set to a first predetermined level at step 304, for example 17 Torr, and the second stage oxygen pressure is set at step 306 to a second predetermined level, for example 4 Torr. Oxygen is delivered through the oxygen delivery system and introduced into the chamber until the oxygen pressure level in the chamber reaches a first predetermined pressure level at step 308, for example 3×10⁻⁸ Torr. Strontium and titanium are introduced into the chamber, through the use of shutters for example, and a desired thickness of STO, say 1 nm, is deposited before the partial pressure of oxygen in the chamber rises to a second predetermined level at step 310, for example 3×10⁻⁷ Torr. Then the partial pressure of oxygen in the chamber is maintained at its second predetermined level, being 3×10⁻⁷ Torr in this example, by adjusting the second stage pressure level at step 312, from for example 4 Torr to 3.5 Torr.

FIG. 16 shows an example of an oxygen profile 400 achieved with the two-stage system of the present invention using the measurements and settings described in the process 300 example. Profile 400 shows time (in minutes) on the horizontal axis 402 and oxygen partial pressure (measured in Torr) on the vertical axis 404 measured in a MBE chamber. As can be seen from the profile 400, a constant pressure level can now be maintained and regulated after a short time frame. In this example, it took approximately 3 minutes for the pressure level to stabilize.

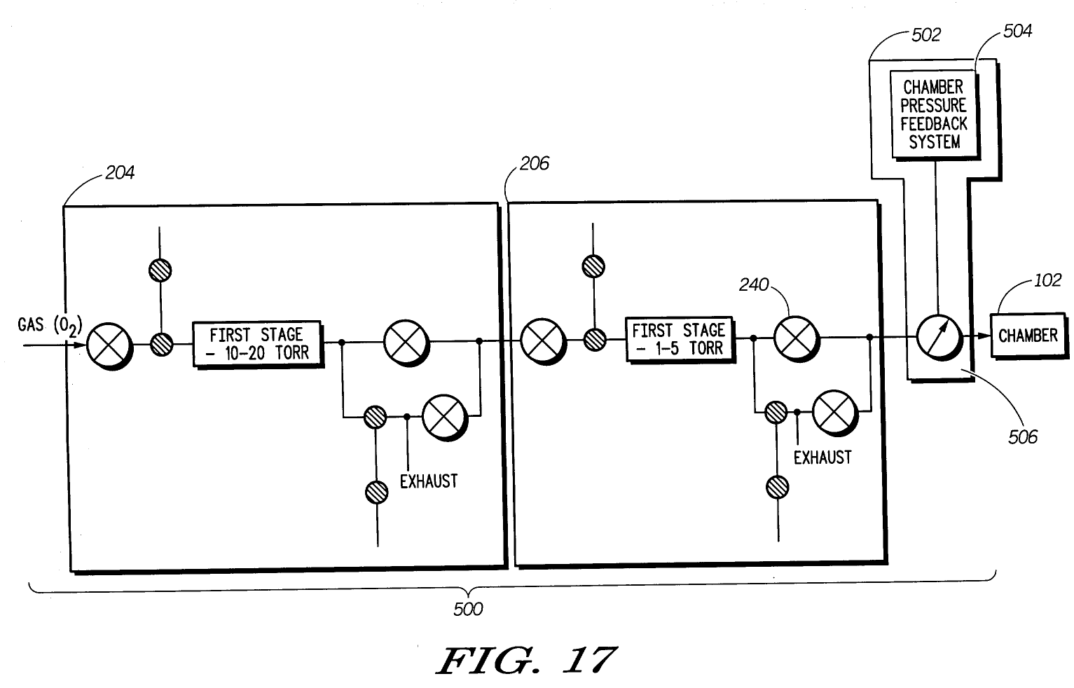

The relationship between the oxygen partial pressure in the second stage and the oxygen partial pressure in the chamber depends on several factors including the chamber size and its corresponding pumping capacity. FIG. 17 schematically illustrates an expansion of the system of FIG. 14 in accordance with an alternative embodiment of the invention. Oxygen delivery system 500 is similar to that shown in FIG. 14 (with like numerals carried forward) and with the further addition of an oxygen pressure feedback path 502. The feedback path 502 enhances the oxygen delivery system's capability to achieve desired oxygen profiles in the chamber 102. The feedback path 502 is preferably positioned between the chamber 102 and the second stage 206 and measures one or more of a variety of chamber characteristics. For example, the feedback path 502 can consist of a chamber pressure feedback system 504 which reads the chamber pressure (this can be an ion gauge reading and/or a residual gas analyzer (RGA) reading) and controls a needle valve 506 positioned between the chamber and the second stage 206. The needle valve 506 is automatically controlled to achieve desired oxygen profile (partial pressure and/or ramp rate) in the chamber 102.

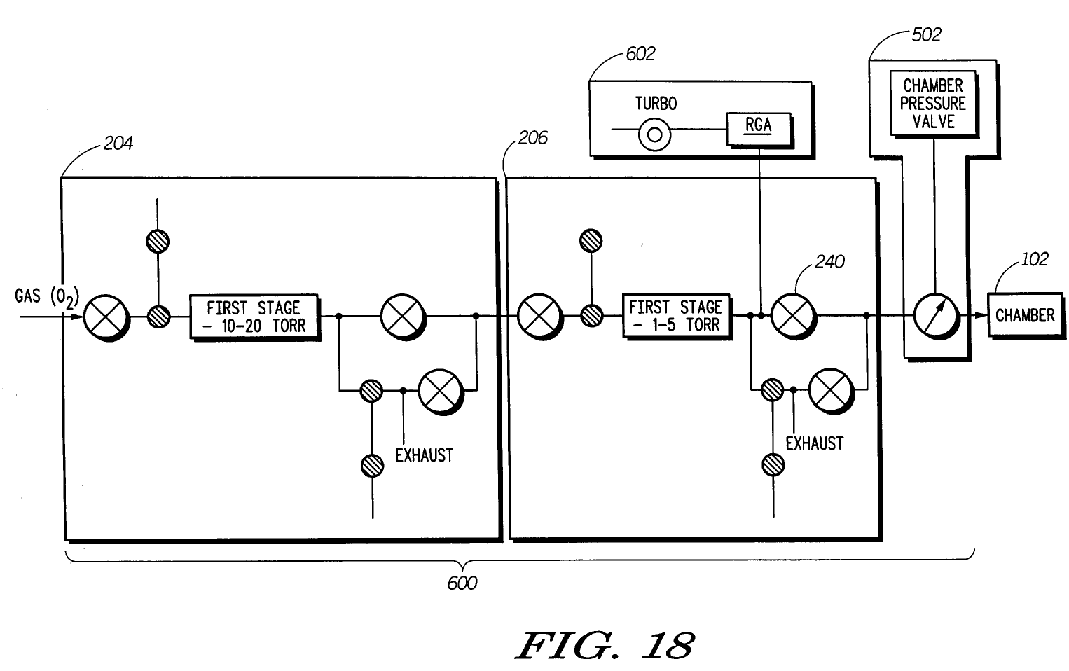

Referring now to FIG. 18, a dual stage pressure control system 600 is formed in accordance with another alternative embodiment of the invention. System 600 is similar to systems 200 and 500 (with like reference numerals carried forward) and further includes a differentially pumped RGA 602 coupled to the second stage 206. The RGA 602 provides the added benefit of real-time gas content feedback. In system 600, the RGA 602 determines the composition and pressure of the delivered gas giving this dual stage system 600 improved accuracy in controlling chamber profiles and helps determine, if any, leakage and contamination in the oxygen delivery system.

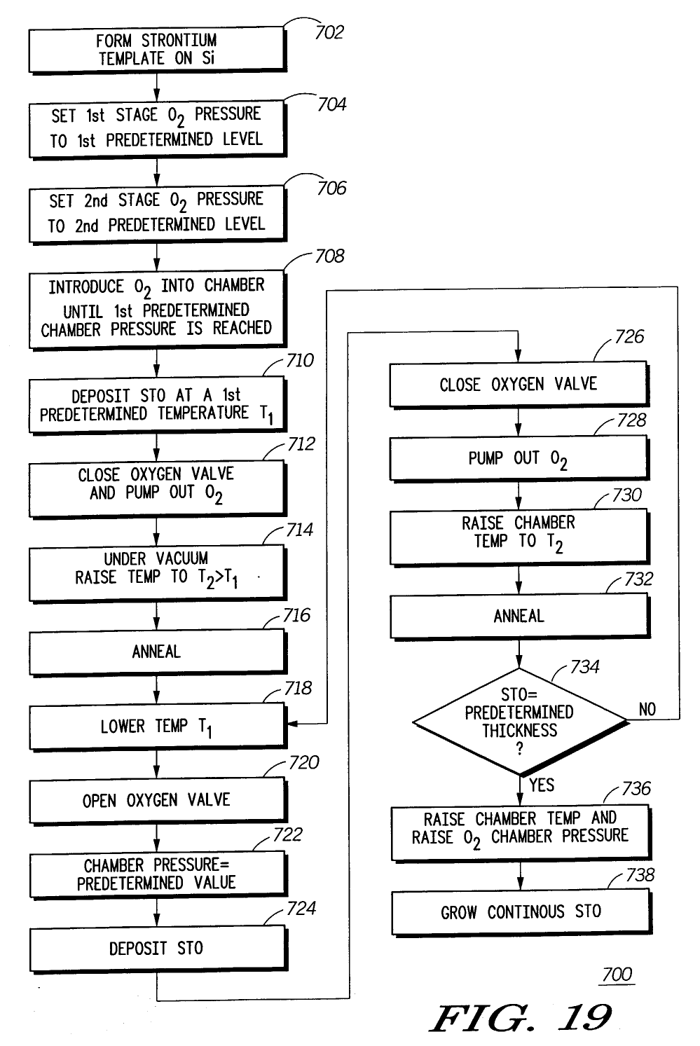

The dual stage oxygen delivery system of the present invention also provides benefits to systems where oxygen needs to be frequently shut off and reintroduced. The following describes an example of such a process. Referring to FIG. 19, there is shown a flowchart depicting an exemplary process 700 of forming an oxide material over a monocrystalline substrate for subsequent III-V growth (or other subsequent growth as described with reference to FIGS. 1-12) using a two-stage deposition approach in accordance with an alternative embodiment of the invention. Process 700 describes forming an STO buffer layer on a silicon substrate but applies to other oxides and monocrystalline substrate materials as well. Process 700 teaches a two-stage deposition approach in accordance with this alternative embodiment. Process 700 begins similarly to process 300 by forming a strontium template at step 702, for example a 2× template, on the silicon. The first-stage oxygen pressure is then set at step 704 to a first predetermined pressure level, for example 17 Torr, and the second stage oxygen pressure level is set at step 706 to a second predetermined pressure level, for example 4 Torr. The oxygen valve 240 is opened and oxygen is delivered through the oxygen delivery system and introduced into the chamber until the oxygen pressure level reaches a first predetermined pressure level at step 708, for example 3×10⁻⁸ Torr in the chamber. A deposit of 0.4-1.0 nm of STO at a low predetermined temperature occurs at step 710, for example a temperature of less than 300 degrees C. Next, the oxygen valve 240 is closed and oxygen valve 241 is opened and residual oxygen is pumped out at step 712. Under vacuum or very low oxygen partial pressure conditions, a sample temperature is raised to a high temperature (for example (650-750 degrees C.) at step 714, and then an anneal is performed at step 716, for approximately 1-30 minutes.

The temperature is then lowered back down to the lower temperature at step 718, in this case 300 degrees C. The oxygen valve 240 is opened at step 720 to introduce oxygen into the chamber and a wait of approximately 30 seconds takes place while the oxygen pressure increases to about 1×10⁻7 Torr in the chamber at step 722. Next, a deposit of 0.4-1 nm of STO occurs at step 724. The oxygen valve 240 is then closed at step 726, and the oxygen is pumped out through valve 241. Under vacuum conditions, a sample temperature is raised to a high temperature again (e.g. 650-750 degrees C.) at step 730. Finally, an anneal step is performed for approximately 1-30 minutes at step 732, and the thickness of the STO is checked at step 734.

Steps 718-734 account for a cycle of deposition of STO. Steps 718-734 are repeated until the STO is thick enough as determined at step 734 (e.g. 2-10 nm to maintain its integrity at high temperature and relatively high oxygen pressure. Once the desired thickness is achieved at step 734, the chamber temperature is raised back to the high temperature again (here greater than 700 degrees C.) and the chamber pressure of oxygen is raised (here greater than 2×−7 Torr) at step 736 such that STO is continuously grown two dimensionally at step 738 at this temperature and oxygen pressure.

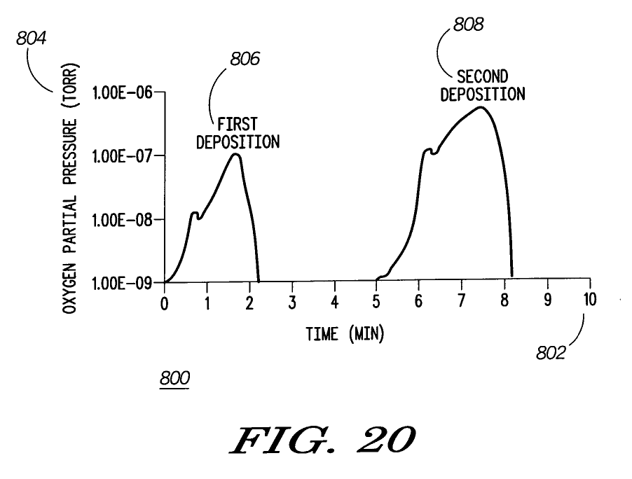

An example of an oxygen profile achieved with the two-stage system using the two-stage deposition approach discussed above with reference to process 700 is shown in the profile 800 of FIG. 20. Profile 800 includes time on the horizontal axis 802 and oxygen partial pressure (measured in Torr) on the vertical axis 804. The first STO deposition is shown at 806 and the second STO deposition is shown at 808. The first deposition of STO occurred in conjunction with step 710 of process 700, and the second deposition of STO occurred at step 724. The profile 800 represents how oxygen can be turned off and reintroduced so that STO can finally be built in optimally controlled conditions.

Accordingly, there has been provided an oxygen delivery system that automatically controls and adjusts at least one oxygen control parameter such that oxygen gas introduced into a chamber can be monitored and controlled to provide a desired oxygen profile within the chamber. The oxygen delivery system of the present invention provides improved oxide growth and is particularly advantageous to MBE systems where the need for manual control has been eliminated.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. An oxygen delivery system for delivering oxygen to a chamber, comprising:
an input for receiving oxygen gas;
a first stage coupled to the input, the first stage providing a first controllable oxygen parameter;
a second stage coupled to the first stage, the second stage providing a second controllable oxygen parameter;
an output coupled to the chamber; and
the first and second controllable oxygen parameters providing a controllable oxygen profile within the chamber.

2. The oxygen delivery system of claim 1, wherein the first stage comprises a first pressure control device, and the second stage comprises a second pressure control device.

3. The oxygen delivery system of claim 1, wherein the first stage comprises an oxygen pressure control device, and the second stage comprises an oxygen flow control device.

4. The oxygen delivery system of claim 1, wherein the first stage comprises an oxygen flow control device, and the second stage comprises an oxygen pressure control device.

5. The oxygen delivery system of claim 1, wherein the first stage comprises a first oxygen flow control device, and the second stage comprises a second oxygen flow control device.

6. The oxygen delivery system of claim 1, wherein the first stage comprises a baratron controlled throttle valve to control pressure.

7. The oxygen delivery system of claim 1, wherein the first stage comprises a baratron controlled throttle valve to control pressure, and the second stage comprises a leak valve to limit the flow of oxygen into the chamber.

8. The oxygen delivery system of claim 1, wherein the first stage comprises a mass flow controller (MFC), and the second stage comprises a pressure control device to control a partial pressure of oxygen.

9. The oxygen delivery system of claim 1, further including a turbo controlled differentially pumped residual gas analyzer (RGA) coupled to the second stage.

10. A system for forming a semiconductor structure, comprising:
a chamber;
a plurality of material sources coupled to the chamber for providing an oxide film on a substrate, said plurality of material sources including an oxygen source; and
an automatic oxygen delivery system coupled to the chamber, the automatic oxygen delivery system comprising a plurality of stages, each stage providing automatic control of one or more oxygen control parameters.

11. The system of claim 10, wherein the one or more oxygen control parameters include at least one of oxygen ramping rate, steady state partial pressure, flow rate.

12. A method of forming a semiconductor structure by the process of molecular beam epitaxy, comprising:
forming a monocrystalline substrate with an overlying oxide layer, the overlying oxide layer being formed from a plurality of gaseous sources including an oxygen gaseous source delivered by an automated oxygen delivery system; and
forming a monocrystalline material layer overlying the oxide layer.

13. The method of claim 12, wherein the monocrystalline substrate comprises a monocrystalline silicon substrate.

14. The method of claim 13, wherein the monocrystalline material layer comprises a monocrystalline gallium arsenide compound semiconductor layer.

15. A semiconductor structure, comprising:
a monocrystalline substrate;
an oxide layer formed over the monocrystalline substrate, the oxide layer formed by a plurality of gaseous sources including an oxygen gaseous source delivered by an automated oxygen delivery system; and
a monocrystalline material layer overlying the oxide layer.

16. The semiconductor of claim 15, wherein the monocrystalline substrate comprises a monocrystalline silicon substrate.

17. The semiconductor of claim 15, wherein the monocrystalline material layer comprises a monocrystalline gallium arsenide compound semiconductor layer.

18. A semiconductor manufacturing system, comprising:
a molecular beam epitaxy (MBE) deposition chamber;
a plurality of gaseous sources coupled to the deposition chamber; and
an automated oxygen delivery system coupled to the deposition chamber.

19. The semiconductor manufacturing system of claim 18, wherein the oxygen delivery system comprises a two stage oxygen delivery system providing first and second oxygen control parameters.

20. The semiconductor manufacturing system of claim 19, wherein the first and second oxygen control parameters are selected from oxygen pressure control, oxygen ramp rate control, oxygen flow control.

21. The semiconductor manufacturing system of claim 20, wherein the oxygen pressure control is controlled by a pressure control system formed of a plurality of plunger valves, valves, and exhaust operatively coupled together under microprocessor control.

22. The semiconductor manufacturing system of claim 20, wherein the oxygen flow control is provided by a mass flow controller (MFC).

23. The semiconductor manufacturing system of claim 19, further comprising a feedback path between the chamber and a second stage of the two-stage system, the feedback path providing a reading of chamber pressure.

24. The semiconductor manufacturing system of claim 23, wherein the feedback path comprises a needle valve coupled between the chamber and the second stage.

25. The semiconductor manufacturing system of claim 18, further comprising a needle valve responsive to chamber pressure.

26. The semiconductor manufacturing system of claim 19, further comprising a needle valve automatically responsive to chamber gas flux readings to achieve desired gas profile in the chamber.

27. A method of forming an strontium titanate (STO) accommodating buffer layer over a silicon substrate, comprising:
providing a silicon substrate in a chamber;
forming an accommodating buffer layer over the substrate by:
introducing oxygen into the chamber;
waiting for the partial pressure of oxygen to reach a first predetermined level in the chamber;
introducing strontium and titanium into the chamber;
allowing the partial pressure of oxygen in the chamber to rise to a second predetermined level; and
decreasing the second stage pressure level to maintain the partial pressure of oxygen in the chamber at a final predetermined level thereby forming the accommodating buffer layer of STO.

28. The method of claim 27, further comprising:
repeatedly turning the oxygen off and reintroducing the oxygen into the chamber so as to create multiple depositions of STO until a predetermined thickness of STO is reached.
